(19) United States
(12) Patent Application Publication
(10) Pub. No.: US 2022/0396473 A1
(43) Pub. Date: Dec. 15, 2022

(54) Sensor Device with Cover Layer

(71) Applicants: MEAS France, Toulouse (FR); MEAS France, Toulouse (FR)

(72) Inventors: Emilien Durupt, Toulouse (FR); Damien Andreu, Toulouse (FR)

(73) Assignee: MEAS France, Toulouse (FR)

(21) Appl. No.: 17/840,955

(22) Filed: Jun. 15, 2022

(30) Foreign Application Priority Data
Jun. 15, 2021 (EP) 21305817.5

(51) Int. Cl. B81B 7/00

(52) U.S. Cl. CPC B81B 7/0058; B81B 2201/0292; B81B 2203/0353

(57) ABSTRACT

A sensor device includes a substrate, a sensing layer formed over the substrate, and a cover layer at least partially covering the sensing layer and protecting the sensing layer. The cover layer is a porous material or has a plurality of openings.

### CROSS-REFERENCE TO RELATED APPLICATIONS

This application claims the benefit of the filing date under 35 U.S.C. § 119(a)-(d) of European Patent Application No. 21305817.5, filed on Jun. 15, 2021.

### FIELD OF THE INVENTION

The present invention relates to a sensor device for sensing a measurand, for example, the absolute or relative humidity of an environment, and, in particular, the protection of a sensing layer of the sensor device used for the sensing operation.

### BACKGROUND

Sensors are of growing importance and are becoming more ubiquitous in every-day life. For example, microelectromechanical systems (MEMS) are an attractive option to answer the demand for increased performance of sensors along with decreased sizes and costs. For example, temperature sensors and humidity sensors or a combination thereof are known to be used in a large variety of applications including windshield sensing devices installed in vehicles for the purpose of automatically controlling the heating, ventilation, air conditioning and operation of the windshield wiper.

In the art, a humidity sensor device is known that comprises a dielectric substrate, two electrodes formed on the dielectric substrate and a sensitive layer for absorption and/or adsorption of water. A variation of capacitance, electrical conductivity, electrical resistivity or impedance caused by the absorption and/or adsorption of water can be measured and used for the determination of the (relative) humidity of an environment under the assumption that the water amount detected by the sensor is in thermal equilibrium with the gaseous fraction of water in the environment.

The sensing layer of the sensor device may be made of an organic polymer material. However, organic materials suffer from degradation during lifetime and are affected by relatively high temperatures that, for example, arise during the process of manufacturing of the sensor device or in-the-field operation in particular applications. Additionally, response times of conventional polymeric humidity sensor devices are relatively low (on the order of seconds). Therefore, recently, completely inorganic humidity sensor devices have been proposed which, for example, comprise inorganic dielectric layers serving as sensing layers.

In any case, the sensing layers or sensing cells comprising the sensing layers must be protected against pollution, for example, present in air the humidity (or any other measurand) of which is to be measured. Pollution/contaminants in form of dust, polls, oil droplets or other material different from water (steam) particles may even cause short-circuiting of the sensing electrode of the sensor devices.

In the art, dust/fluid/mist sensor protections comprise polytetrafluorethylene (PTFE) membranes that are glued on top of the packaged devices in a post packaging step. However, the attachment of the PTFE membranes represents a relatively laborious post-packing manufacturing process and, in addition, the protection quality and reliability of the PTFE membrane protections in harsh operation environments has proven not to be satisfying.

### SUMMARY

A sensor device includes a substrate, a sensing layer formed over the substrate, and a cover layer at least partially covering the sensing layer and protecting the sensing layer. The cover layer is a porous material or has a plurality of openings.

### BRIEF DESCRIPTION OF THE DRAWINGS

The invention will now be described by way of example with reference to the accompanying Figures, of which:

FIG. 1 is a schematic sectional view of a sensor device according to an embodiment;

FIG. 2 is a flowchart of a process of manufacturing a sensor device according to an embodiment;

FIG. 3 is a schematic sectional view of a pre-dicing wafer configuration from which the sensor device shown in FIG. 1 can be obtained; and

FIG. 4 is a schematic sectional view of a sensor device comprising a cover layer with a plurality of openings according to an embodiment.

### DETAILED DESCRIPTION OF THE EMBODIMENT(S)

Features and advantages of the present invention will be described with reference to the drawings. In the description, reference is made to the accompanying figures that are meant to illustrate embodiments of the invention. It is understood that such embodiments do not represent the full scope of the invention.

The present invention provides a sensor device that is, for example, suitable for sensing a (relative) humidity, temperature or pressure of an object or environment. According to the invention, the sensor device comprises a cover layer that comprises or consists of a porous material and/or comprises a plurality of openings. The cover layer provides protection against pollution. The provided sensor device can be manufactured relatively easily by mass production semiconductor manufacturing techniques and, particularly, resists relatively high temperatures and chemically harsh environments.

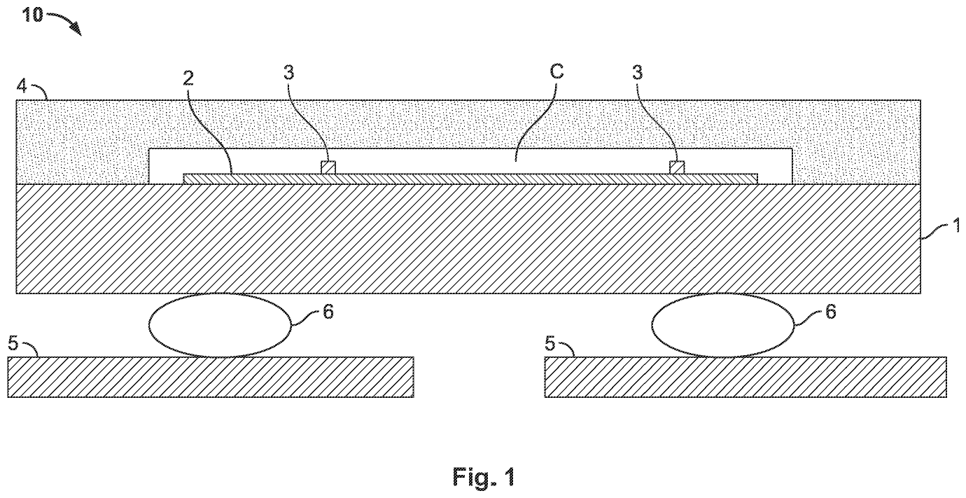

FIG. 1 exemplarily shows an embodiment of a sensor device 10 according to the invention. The sensor device 10 may be configured for sensing a relative humidity and/or temperature or pressure of air or another medium/object. According to the embodiment shown in FIG. 1, the sensor device 10 comprises a substrate 1.

The substrate 1 may be or comprise a semiconductor bulk substrate, a glass (and a borosilicate, in particular), a ceramic or an application-specific integrated circuit (ASIC) or an application-specific standard product (ASSP). The semiconductor bulk substrate can be made of or comprise (poly)silicon. A compact design employing an ASIC or ASSP can be achieved. It is noted that if an ASIC, ASSP, or a heat resistant acquisition circuit is used, some discrete electronics may be provided remotely, particularly, when high-temperature applications are envisaged.

As shown in FIG. 1, the sensor device 10 comprises a sensing layer 2 and a sensor cell comprising a sensing layer 2 and, for example, being wire connected to a printed circuit board, wherein the sensing layer 2 is formed on or over the substrate 1. The sensing layer 2 may be formed directly on the substrate 1 in an embodiment. The sensing layer 2 may be an adsorbing and/or absorbing layer (for example, for adsorbing and/or absorbing water) in the case of a humidity sensor device. In an embodiment, the sensing layer 2 is an inorganic dielectric layer. The inorganic dielectric layer may be a nitride layer, for example, an Si₃N₄ layer. In any case, the sensing layer 2 exhibits detectable and well-defined properties varying in accordance with variations of a measurand.

Sensing electrodes 3 are formed on or over the sensing layer 2. All sensing electrodes 3 can be made of the same material. For example, the sensing electrodes 3 can be made of or comprise a noble metal, in particular, gold, to provide for chemical resistance and durability. Alternative materials that are suitable for manufacturing the electrodes include aluminum and copper.

Voltages can be applied via electrode terminals that can be made of the same material as the sensing electrodes 3. For example, a pair of interdigitated electrodes is formed in the same horizontal plane over the sensing layer 2. It is explicitly noted that the invention is not limited to a particular electrode configuration. The electrodes 3 may be made from the same layer and may terminate in electrode terminals that may also be formed from the same layer.

Formation of the pair of interdigitated electrodes over the inorganic dielectric layer 2 can be facilitated by an adhesion layer formed on the sensing layer 2 wherein the adhesion layer is, for example, made of or comprising Cr.

The sensing layer 2 has physical and/or chemical properties (for example, an electrical conductivity or capacitance between the sensing electrodes 3) that vary depending on the quantity of a measurand (for example, temperature, pressure or humidity).

The sensor device 10 may comprises a sensing circuit configured for measuring at least one of an electrical resistance of the sensing layer 2, an electrical (surface) conductivity of the sensing layer 2, an impedance of the sensing layer 2, a capacity of the capacitor formed by the sensing electrodes 3 and the sensing layer 2 and a current flowing through the sensing layer 2.

The sensing layer 2 (as well as the sensing electrodes 3) is protected against pollution from the environment (for example, dust, pollens, oil droplets, etc. present in air) by a cover layer 4, shown in FIG. 1, formed on or attached to the substrate 1 that forms a cavity C surrounding the sensing layer 3 (without contacting the sensing layer 3). The cover layer 4 may also provide protection against mechanical damage. The cover layer 4 represents a High Efficiency Particulate Filter (HEPF) against contaminants that can easily and relatively cheaply be manufactured and easily formed over the substrate 1.

According to an embodiment, the cover layer 4 comprises or consists of a porous material, for example, a porous ceramic material, particularly, a sintered ceramic material. For example, a sintering process for forming the sintered ceramic material may be performed at a temperature of above 1,500° C. or, depending, on the usage of sintering additives at a temperature of lower than 1,200° C. According to particular embodiments, the ceramic material used for the cover layer 4 is or comprises silicon carbide exhibiting a decomposition temperature of above 2,500° C. According to an alternative embodiment, the porous material is a solid foam material, for example, a metal foam, exhibiting the above-mentioned porosities and/or diameter sizes of the pores. Such foam materials may be advantageous with respect to both durability and light weight.

Moreover, the porous material may have a porosity of more than 5% or 50%, in an embodiment, more than 60% or 70%. For applications with slowly varying measurands a porosity of less than 5% might also be considered suitable, in principle.

For example, the porous material comprises pores with average diameters of 5 nm to 200 μm, for example, 100 nm to 300 nm. The cover layer 4 may have a thickness of 100 nm to 10000 μm, for example, 200 μm to 600 μm, or 5000 to 10000 μm. Thus, the cover layer 4 allows for effective filtering of contaminants together with keeping short (for example, sub-second) response times provided by the sensor device 10. In this context, it is to be understood that the pore and opening sizes can be adjusted to actual applications to prevent contamination, in particular, to particle sizes of contaminants.

As shown in FIG. 1, the sensor device 10 can be connected to an electronic equipment/circuitry 5 by solder bumps 6 formed on a lower surface of the substrate 1.

In an embodiment, a current flowing through the sensor layer 2 between the (for example, interdigitated) electrodes 3 or an electrical resistance or electrical (surface) conductivity exhibited by the sensing layer 2 between the (for example, interdigitated) electrodes 3 may be determined as a function of the relative humidity giving rise to the adsorption of water in the sensing layer 2 or as a function of another measurand.

For example, in the case of a humidity sensor device, by an appropriate circuitry the amount of water absorbed/adsorbed by the sensing layer 2, for example, the inorganic dielectric layer mentioned above, can be determined and based on the determined amount of water the humidity or relative humidity of an environment can be determined given that the temperature of the environment is known. The temperature of the environment can be determined by a temperature sensor that may be comprised in the humidity sensor device (combined humidity and temperature sensor) or an additional temperature sensor that may also comprise a cover layer similar to the above-described cover layer 4. As already mentioned, the inventive sensor device itself may be a temperature sensor device or a pressure sensor device. Moreover, a number of sensing elements of a combined sensor device, for example sensing elements for sensing pressure, humidity, temperature, etc., may be covered by the same protection layer.

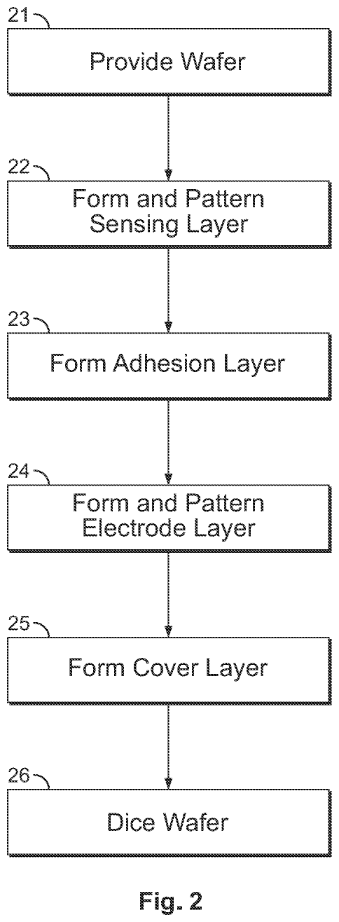

A process of manufacturing a sensor device according to an embodiment of the invention will now be described with reference to FIG. 2. For example, by the process flow illustrated in FIG. 2 the sensor device 10 shown in FIG. 1 can be produced.

As shown in FIG. 2, a wafer, for example, an ASIC wafer, is provided 21 and a sensing layer, for example, in form of an inorganic dielectric layer, for example, an Si₃N₄, layer is continuously formed, for example, grown, and patterned 22 over the wafer. The sensing layer may be part of a sensor cell formed over the wafer. After the formation and patterning 22 of the sensing layer, an adhesion layer, for example, a Cr layer, is formed 23 over the patterned sensing layer and an electrode layer, for example, an Au layer, is formed and patterned 24 over the adhesion layer. The formation of the electrode layer may comprise vapor deposition and the patterning may comprise the formation of a photoresist (positive or negative) and subsequent photolithography processing and reactive ion etching or wet etching.

In step 25 of the flowchart shown in FIG. 2, a cover layer is formed on or over the wafer and at least partially, and in an embodiment continuously, over the sensing layer. A method comprising the formation of the continuous cover layer in the context of wafer scale assembly may be advantageous in mass production. Thus, a wafer scale (wafer bonding) assembly of the continuous cover layer onto the finalized wafer, for example, ASIC wafer, may be selected. The continuous cover layer can be attached to the wafer in the clean room before dicing and packaging.

The cover layer comprises or consists of a porous material, for example, a porous ceramic material as, for example, silicon carbide, and, in particular, a sintered ceramic material. For example, a sintering process for forming the sintered ceramic material may be performed at a temperature of above 1,500° C. or, depending, on the usage of sintering additives at a temperature of lower than 1,200° C. Alternatively, the porous cover layer may comprise or consist of a foam material, for example, metal foam.

Moreover, the porous material used for the cover layer may have a porosity of more than 5% or 50%, or more than 60% or 70%. For example, the porous material comprises pores with average diameters of 5 nm to 200 μm, or in another embodiment, 100 nm to 300 nm. The cover layer may have a thickness of 100 nm to 10000 μm, 200 μm to 600 μm, or 5000 to 10000 μm. The cover layer is formed to provide protection for the sensing layer and electrodes against pollution and may also provide mechanical protection.

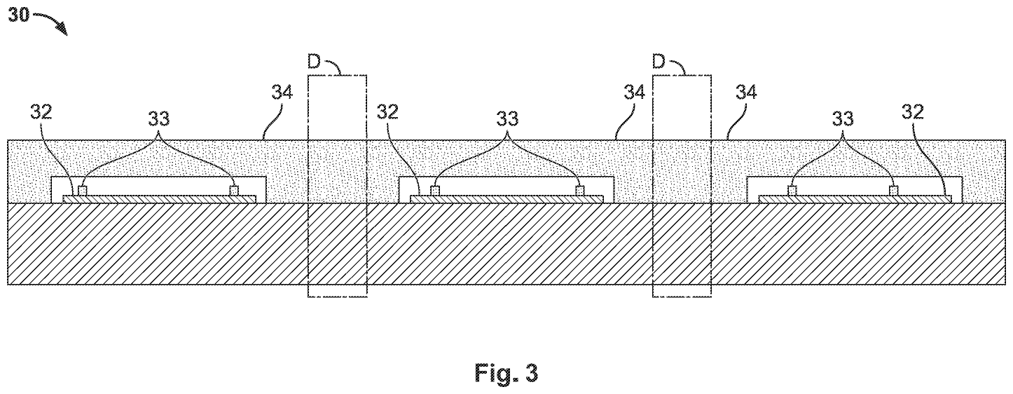

A typical pre-dicing wafer configuration 30 that results after the completion of step 25 of FIG. 2 is shown in FIG. 3. On the wafer 31, a plurality of sensing layers 32 are formed and, over the plurality of sensing layers 32, a plurality of sensing electrodes 33 are formed. Each of the plurality of sensing layers 32 is protected by a porous (for example, ceramic or solid foam) cover layer 34 continuously formed over the wafer 31. Individual dies for individual (intermediate) sensor devices can be formed by dicing at the dicing regions D shown in FIG. 3.

Thus, the pre-dicing wafer configuration 30 resulting after step 25 of FIG. 2, for example, the configuration illustrated in FIG. 3, is diced/cut in order to produce individual dies (see step 26 of FIG. 2) comprising individual cover layers. It is noted that, according to an alternative embodiment, no continuous cover layer is formed in the pre-dicing wafer configuration and, rather, individual cover layers are attached to the dies after dicing of the wafer. Electrode terminals can be used for wire bonding to a printed circuit board by, for example, suitable wires. The printed circuit board may comprise a measuring and control circuitry for processing sensed data and controlling the sensor device resulting from the manufacturing process illustrated in FIG. 2. The printed circuit board may comprise any on-chip circuits that carry out automatic calibration and signal processing.

In the above-described manufacturing process flow, no organic materials need to be involved that are damageable by relative high temperatures involved in the overall mass product manufacturing process. Thereby, the ageing characteristics can be improved as compared to sensor devices comprising organic sensing layers or other organic components. This aspect in combination with the provided cover layer allows for in-situ operation of the obtained sensor device in relatively hot (up to some 1,000° C., for example) and chemically aggressive environments.

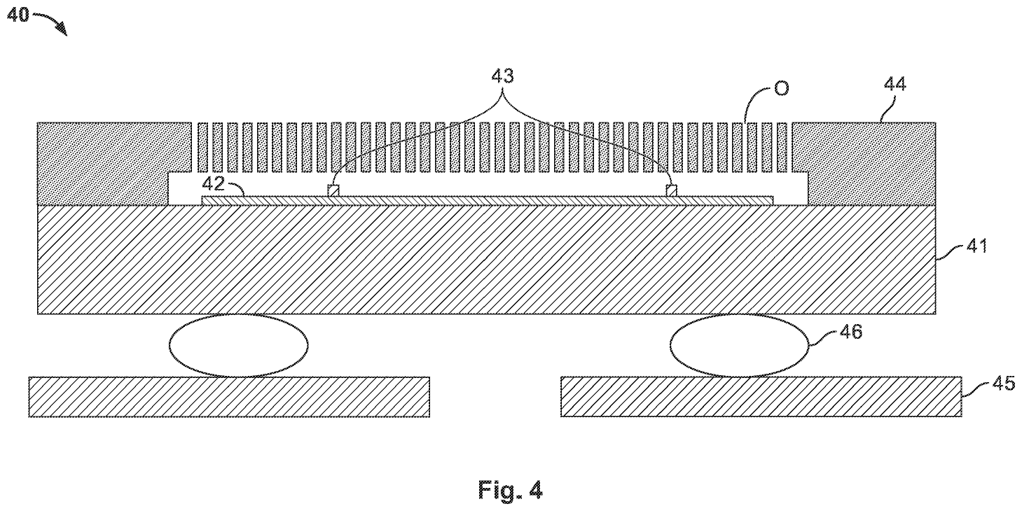

FIG. 4 shows an alternative embodiment of an inventive sensor device 40. It may be manufactured by the same or a similar method as described above with reference to FIGS. 2 and 3. The sensor device 40 comprises a substrate 41, a sensing layer 42, and sensing electrodes 43. The substrate 41, the sensing layer 42, and the sensing electrodes 43 may be the same or similar to the substrate 1, the sensing layer 2 and the sensing electrodes 3 of the embodiment of an inventive sensor device 10 shown in FIG. 1.

Different from the embodiment shown in FIG. 1, the sensor device 40 shown in FIG. 4 comprises a cover layer 44 exhibiting vertical openings O. The openings O can be nano-sized vias with average diameters of 5 nm to 200 μm, or 100 nm to 300 nm. The openings O allow for a fluid communication from the environment of the sensor device 40 to its interior but, due to their sizes, prevent contaminants from entering the sensor device 40 and disadvantageously contacting the sensing layer 42. The openings O take over the role of the pores of the porous material of the cover layer 4 described with reference to FIG. 1.

The cover layer 44 may be made of or comprise a non-porous dielectric and/or metal material. In principle, the cover layer 44 may be made of or comprise a porous material as described above and the openings 44 are additionally provided for enhancing fluid communication. In any case, the openings O may be formed after formation of the cover layer 44, for example, by etching. As shown in FIG. 4, the openings/vias O may run parallel to a thickness direction of the cover layer 44. Alternatively, at least some of them may run at some finite angle to the thickness direction of the cover layer 44.

According to an embodiment, the surfaces or sidewalls of the openings O are coated by some metal material. Thereby, electrostatic filtering properties can be provided that might prove advantageous with respect to the overall filtering/protection efficiency of the cover layer 44.

The sensor device 10 allows for a reliable and permanent sensing operation in harsh environments and that can be manufactured relatively easily. The provided configuration can be easily produced by mass production semiconductor manufacturing processes. It can be manufactured at compact sizes and does not heavily suffer from severe deteriorations due to aging during its lifetime. The device can be manufactured and operated at relatively high temperatures up to about 300° C., for example, or up to 1000° C. or even higher. Moreover, based on such a configuration a response time of less than a second can be achieved.

The sensor device can be used as a stand-alone device for remote sensing in harsh environments characterized by high temperatures (of some 100 to some 1000° C.) and high pressures (for example, a few ten atm or more).

All previously discussed embodiments are not intended as limitations but serve as examples illustrating features and advantages of the invention. It is to be understood that some or all of the above described features can also be combined in different ways.

What is claimed is:

1. A sensor device, comprising:
a substrate;
a sensing layer formed over the substrate; and
a cover layer at least partially covering the sensing layer and protecting the sensing layer, the cover layer is a porous material or has a plurality of openings.

2. The sensor device of claim 1, further comprising a plurality of sensing electrodes formed on or over the sensing layer.

3. The sensor device of claim 1, wherein the porous material has a porosity of more than 5%.

4. The sensor device of claim 3, wherein the porosity is greater than 50%.

5. The sensor device of claim 3, wherein the porous material has a plurality of pores with an average diameter of 5 nm to 200 μm.

6. The sensor device of claim 5, wherein the average diameter is 100 nm to 300 nm. The sensor device of claim 1, wherein the cover layer is a porous ceramic material.

8. The sensor device of claim 1, wherein the cover layer is a porous solid foam material.

9. The sensor device of claim 1, wherein the cover layer is a non-porous material having the plurality of openings.

10. The sensor device of claim 9, wherein the openings have an average diameter of 5 nm to 200 μm.

11. The sensor device of claim 1, wherein the openings have a plurality of sidewalls covered by a metal material.

12. The sensor device of claim 1, wherein the cover layer has a thickness of 100 nm to 10000 μm.

13. The sensor device of claim 1, wherein the cover layer forms a cavity at least partially around the sensing layer.

14. The sensor device of claim 1, wherein the cover layer is attached to or formed partially on the substrate.

15. The sensor device of claim 1, wherein the sensing layer is an inorganic dielectric layer.

16. The sensor device of claim 15, wherein the inorganic dielectric layer is made of or includes a nitride material.

17. The sensor device of claim 1, wherein the substrate is a semiconductor bulk substrate or a semiconductor microcircuit.

18. The sensor device of claim 1, wherein the sensor device senses temperature, pressure, relative humidity, absolute humidity, or a combination thereof.

19. The sensor device of claim 2, further comprising a sensing circuit measuring at least one of an electrical resistance of the sensing layer, an electrical conductivity of the sensing layer, an impedance of the sensing layer, a capacity of a capacitor formed by the sensing electrodes and the sensing layer, and a current flowing through the sensing layer.

20. A method of manufacturing a plurality of sensor devices, comprising:
providing a wafer;
forming a plurality of sensing layers over the wafer;
forming a plurality of sensing electrodes over and/or in the wafer;
forming a continuous cover layer over each of the sensing layers, the continuous cover layer is a porous material and/or has a plurality of openings; and
dicing the wafer to obtain a plurality of intermediate sensor devices each including one of the sensing layers and an individual cover layer formed by dicing the continuous cover layer.
